(19) United States
(12) Patent Application Publication
(10) Pub. No.: US 2011/0073163 A1
(43) Pub. Date: Mar. 31, 2011

(54) PHOTOVOLTAIC LAMINATION AND ROOF MOUNTING SYSTEMS

(76) Inventor: Osbert Hay Cheung, Concord, NC (US)

(21) Appl. No.: 12/566,748

(22) Filed: Sep. 25, 2009

(51) Int. Cl. H01L 31/048; B32B 37/12

(52) U.S. Cl. 136/251; 156/60; 156/71

(57) ABSTRACT

A photovoltaic system including a first component comprising a lamination of a non-glass photovoltaic module and a support panel having flanges positioned along opposing sides, and a second component configured for attachment to a roof and defining corresponding flanges, wherein the flanges of each component are aligned and secured together to attach the first component to the roof and maintain the photovoltaic module in a position elevated from the underlying roof to permit airflow between the module and the roof.

### TECHNICAL FIELD AND BACKGROUND OF THE INVENTION

1. Field of the Invention

The present invention relates generally to the field of photovoltaic modules and associated mounting systems, and more specifically, to light weight photovoltaic laminations and roof mounting systems configured to permit air flow for cooling purposes and which mount to existing roof structure without compromising the sealing integrity of the roof.

2. Background of the Invention

The drive for renewable energy alternatives has brought about advances in photovoltaic technology, which has been accompanied by the development of installation environments and mounting systems. Photovoltaic modules, commonly referred to as “solar cells” or “solar panels,” have conventionally included a plurality of modules electrically interconnected and encapsulated between various layers of materials, typically glass, metals and adhesives. While glass as a protective cover layer is advantageous in that it is durable and provides rigidity to a panel, it is disadvantageous in that it is heavy, cannot easily be cut to provide custom on-site installations, and breaks typically result in destruction of the entire panel. Further, glass panels absorb heat, which decreases the performance of the panel, and also increase the heat absorption of the roof structure upon which the glass panel in installed.

To mount glass-based photovoltaic modules to roof structures, many conventional designs require elaborate, costly mounting systems capable of supporting the weight of the panels. These conventional mounting systems have further commonly required penetrating the roof structure to locate adequate support to attach the mounting systems and glass panels thereto. While the use of solar panels is environmentally conscious and responsible for both residential and commercial applications, compromising the sealing integrity of the underlying roof may potentially offset the advantages of installing solar panels.

Accordingly, what is desired are photovoltaic modules and mounting systems that are readily installed, relatively simple in design, inexpensive to manufacture, durable, and do not compromise the sealing integrity of the underlying roof.

### BRIEF SUMMARY OF THE INVENTION

To overcome the disadvantages of prior art photovoltaic modules and roof mounting systems, in various aspects, photovoltaic laminations including non-glass protective layers and associated systems for mounting the laminations to roof structures and other structures are provided herein.

In one aspect, a photovoltaic lamination is provided including a non-glass protective layer.

In another aspect, a photovoltaic lamination is provided having a high power density.

In yet another aspect, a non-glass photovoltaic lamination is provided that absorbs significantly less heat than glass-based photovoltaic modules.

In yet another aspect, various roof mounts for non-glass photovoltaic laminations are provided configured to maintain the lamination in a position elevated from the underlying roof, thus allowing air flow between the roof and module for cooling purposes.

In yet another aspect, various roof mounts for photovoltaic laminations are provided that mount without penetrating the underlying roof.

In yet another aspect, various roof mounts for photovoltaic laminations are provided configured to position the lamination at a predetermined angle with respect to the underlying roof to optimize performance.

In yet another aspect, a photovoltaic system is provided including a top component comprising a lamination of a photovoltaic module and a support panel, and a bottom component for securing the top component to an underlying roof.

To achieve the foregoing and other aspects and advantages, various embodiments of a photovoltaic lamination and associated roof mounting systems are provided herein. In one embodiment, the system includes a lamination including a photovoltaic module arranged upon a support panel, the support panel defining a generally planar surface for supporting the photovoltaic module and first and second flanges positioned along opposing sides of the support panel and generally perpendicular to the generally planar surface, the first and second flanges extending in the direction away from the photovoltaic module. The system further includes a roof mount underlying the support panel and configured for attachment to an underlying roof, the roof mount including a generally planar base and first and second flanges positioned along opposing sides of the base and generally perpendicular to the base, the first and second flanges of the roof mount extending in the direction toward the support panel. The corresponding flanges of the support panel and the roof mount are aligned and secured together to attach the support panel to the roof mount to position the photovoltaic module in a position elevated from an underlying roof.

In another embodiment, each of the first and second flanges of the support panel and roof mount define at least one opening therethrough for receiving a fastener to secure the support panel and the roof mount together. The base of the roof mount may include an open center portion devoid of material or may include one or more flanges positioned on the base and extending upwardly toward the overlying support panel for support and breaking up the airflow beneath the panel. The support panel may define a surface area larger than the surface area of the photovoltaic module.

In another embodiment, the first flange of either the support panel or the roof mount has a length greater than its corresponding second flange in order to position the photovoltaic module at an angle with respect to the underlying roof mount and optimize performance. In one embodiment, the preferred angle is about 15 degrees relative to horizontal. In one method of attachment, the first and second flanges of the support panel are received between the first and second flanges of the roof mount. In another embodiment, ends of the first and second flanges of the roof mount extend beyond the length of the generally planar surface and are accessible for receiving at least one clamp for securing the first and second flanges to roof structure, such as to raised seams of the roof.

In another embodiment, the photovoltaic module comprises a non-glass protective cover layer, a photovoltaic layer including one or more photovoltaic cells, and a back film layer, wherein the layers are bonded together with layers of adhesive material to form a lamination.

In another embodiment, the photovoltaic system includes a support panel defining a generally planar support surface for supporting a photovoltaic module, and first and second flanges positioned along opposing sides of the support panel and generally perpendicular to the support surface, a photovoltaic module secured to the support surface, and a roof mount underlying the support panel and configured for attachment to an underlying roof, the roof mount comprising a base and first and second flanges positioned along opposing sides of the base and generally perpendicular to the base, wherein the first and second flanges of the support panel and the roof mount are aligned and secured together to attach the support panel to the roof mount to position the photovoltaic module in a position elevated from an underlying roof.

In another embodiment, a roof mounts are provided including a vertically extending member having first and second flanges extending laterally therefrom forming a channel therebetween for retaining a photovoltaic module, and further including a their flange extending laterally from the vertical member for attaching the roof mount to a roof. The distance between the channel and the third flange is dependent upon the desired height of the photovoltaic module from the roof.

Additional features and advantages of the invention will be set forth in the detailed description which follows, and in part will be readily apparent to those skilled in the art from that description or recognized by practicing the invention as described herein.

### BRIEF DESCRIPTION OF THE DRAWINGS

These and other features, aspects and advantages of the present invention are better understood when the following detailed description of the invention is read with reference to the accompanying drawings, in which:

FIG. 1 is a perspective view of a photovoltaic mounting system including a photovoltaic module, a support panel and a roof mount in accordance with an embodiment of the present invention;

FIG. 2 is a detailed perspective view of the photovoltaic mounting system of FIG. 1 shown installed upon a roof;

FIG. 3 is a perspective view of the photovoltaic mounting system shown disassembled;

FIG. 4 is a schematic diagram illustrating the layered construction of the photovoltaic lamination;

FIG. 5 is a perspective view of the underside of the support panel including flanges and stiffening ribs;

FIGS. 6a-c illustrate various lamination methods utilizing a metal support block, metal bars and a shaped heating plate, respectively, for imparting flatness to the support panel during the lamination process;

FIG. 7 is a perspective view of the system of FIG. 1 detailing fastening points for receiving conventional fasteners for securing the support panel to the roof mount;

FIG. 8 is a perspective view of the roof mount shown removed from the system and including an optional open center devoid of material;

FIGS. 9a-d illustrate various alternative roof mounts including a frame for retaining the lamination in an elevated position and flanges for attachment to roof structure;

FIG. 10 is an alternative embodiment of a mounting system including a roof mount configured to provide a predetermined slope to the photovoltaic module or lamination with respect to the underlying roof to optimize performance;

FIG. 11 is an illustration of an alternative embodiment of a roof mount including upwardly projecting flanges operable for supporting the weight of the support panel and reducing the air flow rate beneath the support panel to minimize air lift effort;

FIG. 12 is a detailed perspective view of the construction of a center flange of FIG. 11 made by cutting the roof mount and bending a portion upward to about a 90 degree angle;

FIG. 13 is an alternative embodiment of a mounting system including flanges that extend beyond the lamination configured to receive clamps for securing the system to existing seams of the roof;

FIG. 14 is a perspective view of the system embodiment of FIG. 13 shown secured to a roof including raised seams using a plurality of clamps;

FIG. 15 is a perspective view of an alternative roof mount embodiment for providing a slope to the lamination, wherein the roof mount includes laterally extending flanges for securing the system to a roof; and

FIG. 16 is a side view of the system of FIG. 15 detailing the slope of the lamination.

### DETAILED DESCRIPTION OF THE INVENTION

The present invention will now be described more fully hereinafter with reference to the accompanying drawings in which exemplary embodiments of the invention are shown. However, the invention may be embodied in many different forms and should not be construed as limited to the representative embodiments set forth herein. The exemplary embodiments are provided so that this disclosure will be both thorough and complete, and will fully convey the scope of the invention and enable one of ordinary skill in the art to make, use and practice the invention. Throughout this detailed description, the roof mount components of the systems are described as being mounted upon a roof of a building, however, it is envisioned that the roof mounts and systems provided herein may be installed upon any structure having any surface with only minor modification to the components being required.

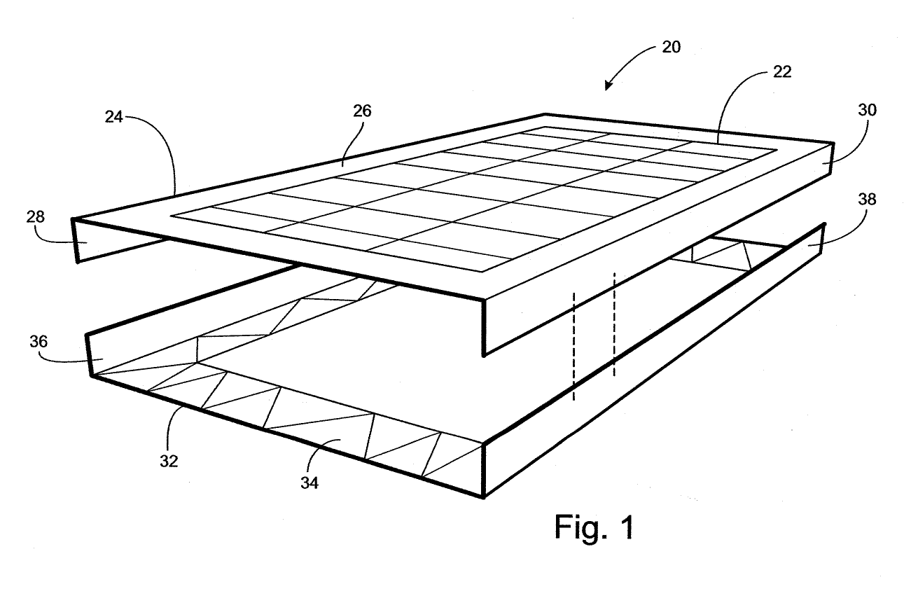

Referring to FIGS. 1-3, a first embodiment of a photovoltaic lamination and associated roof mounting system are shown generally at 20. The system 20 includes a first component or “top” component including a photovoltaic module 22 arranged upon a support panel 24. The photovoltaic module 22 includes a plurality of photovoltaic cells arranged to provide a solar panel having any desired dimension and a generally planar surface. The photovoltaic module 22 and support panel 24 are laminated as described in detail below.

The support panel 24 as shown defines a surface area slightly larger than that of the photovoltaic module 22, thus framing the module to provide protection of the module edges. The support panel 24 may have about the same size as the module 22, such that the maximum amount of surface available is realized for solar collection. The support panel 24 defines a generally planar top surface 26 dimensioned about corresponding to the dimension of the associated photovoltaic module 22. The support panel 24 defines first and second downwardly extending flanges 28, 30 positioned along two opposing sides of the support panel, and preferably along the opposing sides having the greater dimension in embodiments in which the solar panel is not square. The flanges 28, 30 are positioned, such as by being bent, at about perpendicular to the top surface 26. The flanges 28, 30 may have any predetermined height based upon the desired distance of the photovoltaic module 22 from the underlying roof. In one example, a height of about one to several inches in envisioned. The height of the flanges 28, 30 partly determine the air gap provided between the underside of the support panel and the underlying roof. The length and width dimensions of the support panel 24 correspond to those of the underlying roof mount 32 to which is it secured.

The roof mount 32 underlies the support panel 24 and may have the same or a different shape. As shown, the roof mount 32 defines a generally planar base 34 having first and second flanges 36, 38 extending upwardly from the base 34 along two sides, again preferably the sides having the greater dimension in embodiments in which the roof mount 32 is not square. The flanges 36, 38 are positioned, such as by being bent, about perpendicular to the base 34. The flanges 36, 38 have a height corresponding to that of the first and second flanges 28, 30 of the support panel 24 such that the flanges of the support panel 24 seat upon the top surface of the base 34 for support along the length of the sides of the support panel 24. When the support panel 24 and roof mount 32 are secured together, the first and second flanges 28, 30 of the support panel 24 are preferably received between the first and second flanges 36, 38 of the roof mount 32 to prevent the flanges of the support panel 24 from directly contacting the roof surface.

The material used for the support panel 24 and roof mount 32 may be any rigid material capable of supporting the weight of the photovoltaic module 22 while maintaining its shape throughout the lifespan of the system. Metal is preferable as it may be readily bent to form the flanges and remains rigid regardless of the temperatures ranges likely to be experienced. Suitable examples of metal include galvanized steel and aluminum. As described below, the thickness of the material needed to prevent sagging across the short dimension of the support panel 24 may be reduced as the lamination of the support panel and photovoltaic module imparts rigidity to the support panel.

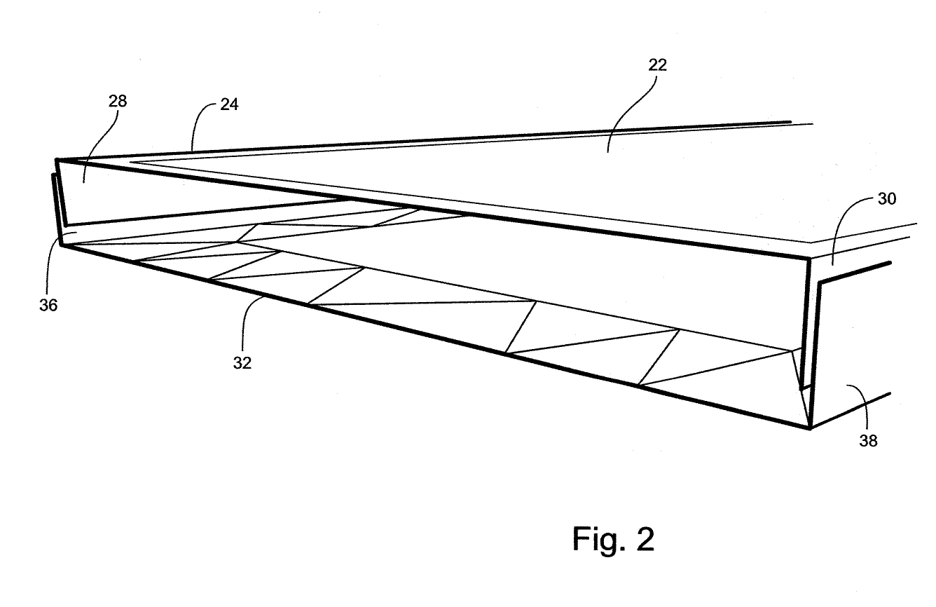

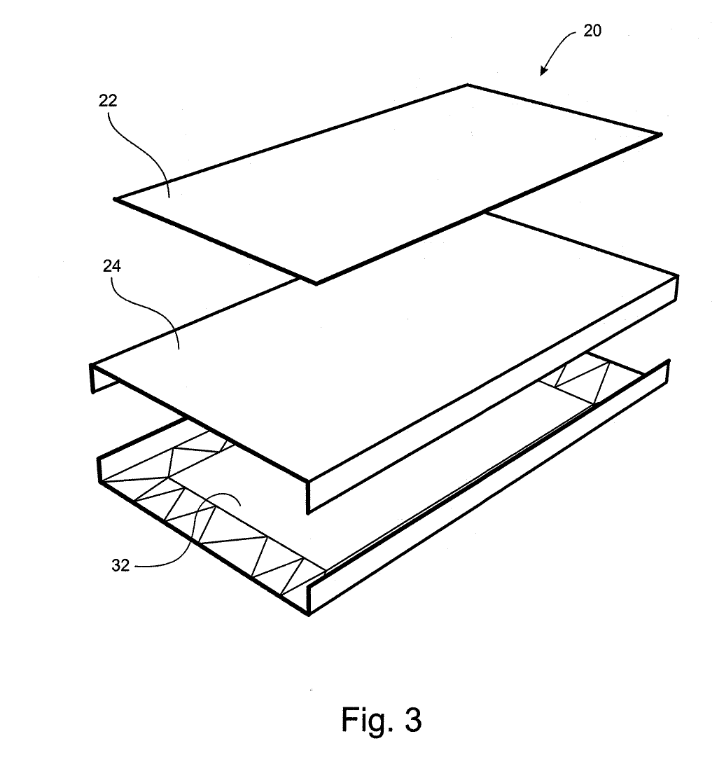

Referring specifically to FIG. 1, the support panel 24 is shown ready to be installed upon and secured to the underlying roof mount 32. Referring specifically to FIG. 2, a detailed view of the support panel 24 being partly installed upon the roof mount 32 is illustrated. Referring specifically to FIG. 3, the photovoltaic module 22, support panel 24 and roof mount 32 are shown disassembled. As described in detail below, the support panel 24 may be secured to the roof mount 32 using any conventional fastener, preferably received through corresponding openings defined through aligned flanges. As shown in FIG. 2, a pair of the opposing sides of each of the support panel 24 and roof mount 32, preferably the shorter dimension side, do not include flanges, thus leaving the assembled system open on the ends to permit air to flow therethrough between the support panel 24 and the roof mount 32. This airflow removes heat from the photovoltaic module 22 thereby increasing performance, as well as prevents/removes heat build up at the roof surface.

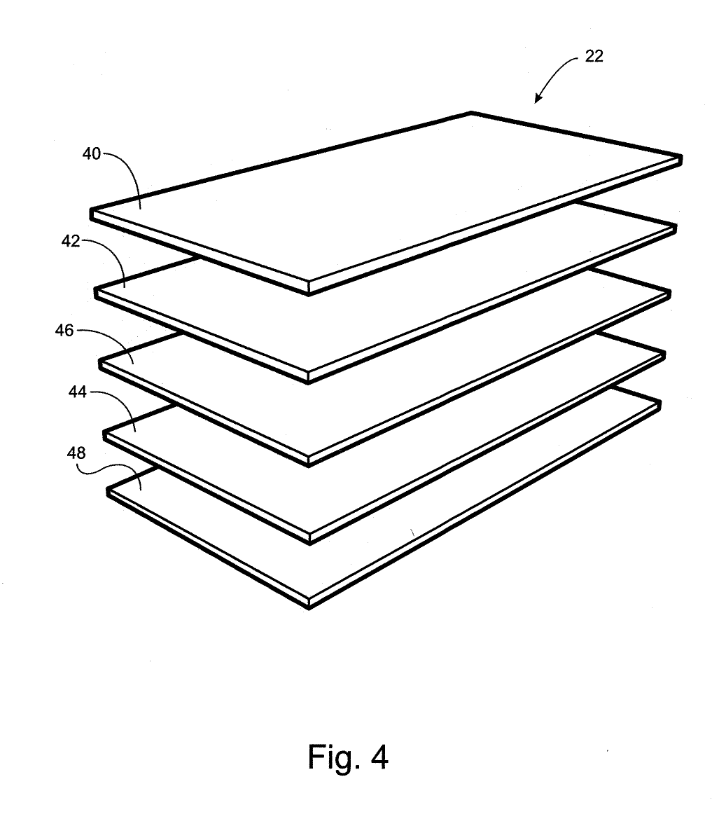

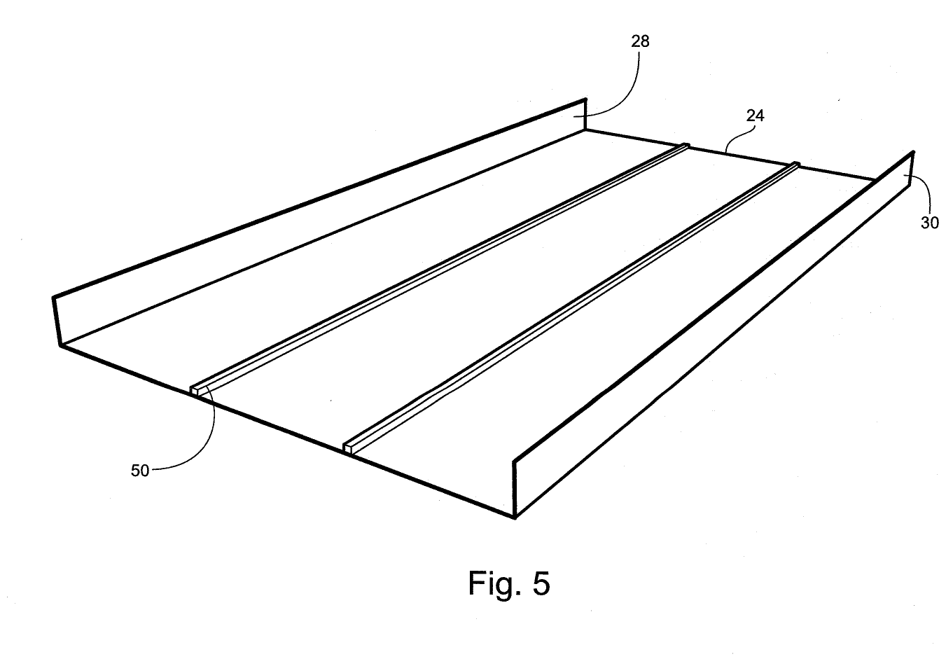

Referring to FIG. 4, the photovoltaic module 22 is constructed from an arrangement of layers to provide the efficient transmission of sunlight upon one or more solar cells encapsulated within the module. The module includes a plurality of layers adhered or bonded together with layers of adhesive material to form a lamination. The module 22 includes a top, transparent, protective cover layer 40 such as a polymer film, adhesive layers 42, 44, photovoltaic layer 46, and a back film 48. The cover layer 40 and photovoltaic layer 46 are adhered or bonded with the first adhesive layer 42. The cover layer 40 faces the sun and serves to protect the module 22 from exterior contaminants, weather conditions and physically applied damage. The underlying photovoltaic layer 46 includes at least one photovoltaic cell associated therewith for directly receiving sunlight and producing electrical current.

Suitable examples of protective cover layer materials include, but are not limited to, fluoropolymer films such as ethylene tetrafluoroethylene (ETFE), perfluoro alkoxy, fluorinated ethylene propylene, polyvinylidene fluoride, tetrafluoroethylene hexafluoropropylene vinylidene fluoride, and other fluoropolymer materials such as Tefzel and polyvinyl fluoride (PVF). Additional materials include PMMA, acrylic plastic film, or combined polyfluoro polymer with other plastic film such as polyester (PET/PEN). These types of preferred films are lightweight, flexible or rigid, inexpensive and have excellent weathering performance results. The cover layer 40 may be optically transparent, possess a matte finish or possess a gloss finish. Each of the photovoltaic cells may be a mono-crystalline cell, multi-crystalline cell, amorphous silicone photovoltaic cell, or a compound semiconductor photovoltaic cell. Preferred photovoltaic cells of the module are of the multi-crystalline type due to cost and their ability to sustain a longer period in which to generate electricity. The plurality of photovoltaic cells are connected by suitable electrical conductors connected to a central electrical network, not forming a part of the invention. The cells may be different colored. The cells are encapsulated within the module by the layers described herein.

The adhesive layers function to encapsulate the photovoltaic cells and bond to hold layers to form a unitary structure. The adhesive layers preferably include at least one of a thermoplastic polyolefin, a thermoplastic polyurethane, a thermoplastic polyester and a thermoplastic ionomer. Suitable examples of materials comprising the adhesive layers include, but are not limited to, heat-activated adhesives such as the copolymer film ethylene vinyl acetate (EVA), thermoplastic polymers such as XUS® available from Dow Chemical, Surlyn® available from Ionomer, thermoplastic urethanes such as Baeyer's Dureflex®, and other polyolefin polymers such as ethylene-methyl acrylate copolymer (FMA), silicone resin, and the like.

The back film 48 functions to insulate the electrical current generated from the photovoltaic cells, protect the photovoltaic cells from environmental impact, and maintain the structural stability of the cells. A variety of materials may be utilized for a back film protection layer, the most common of which include a polyfluoro polymer sold under the brand name Tedlar® by DuPont. Alternative materials include EPDM film, polyester polymers, and nylon-based and cotton-based films/sheets are also suitable for use in this application. EPE from Madico is a preferred film. Tedlar is preferred as it is chemically and UV-resistant. The back film 48 may have a thickness between about 0.005 inches and about 0.040 inches in an exemplary embodiment. The back film 48 may be colored to suit the proper solar panel application.

Referring to FIG. 5, the underside of the support panel 24 is illustrated. The support panel 24 functions to provide rigidity to and protect the photovoltaic cells from bending or cracking, as well as protect the photovoltaic module 22 from environmental impact. As shown, the support panel 24 includes laterally spaced-apart stiffening ribs 50 extending parallel to the longitudinal axis of the support layer and to one another. In alternative embodiments, the support panel 24 may include stiffening ribs extending perpendicular to the longitudinal axis or at an angle to the longitudinal axis, or combinations thereof. In one example, the support panel 24 can support a weight load greater than about 45 lbs/sq. ft, and the stiffening ribs may be provided/arranged to achieve this level of support. The support panel 24 may be constructed from an aluminum composite material, steel sheet or other metal or rigid material as mentioned above.

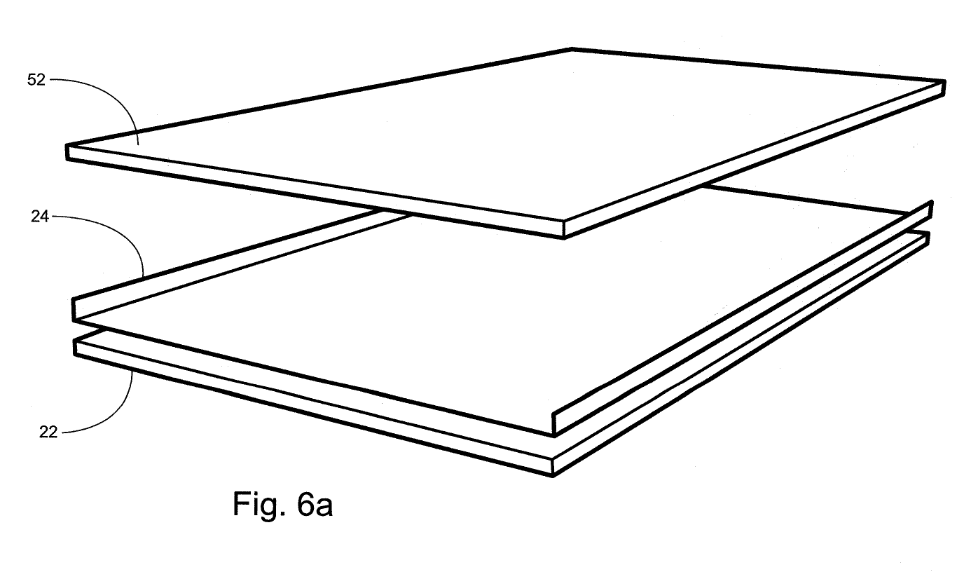

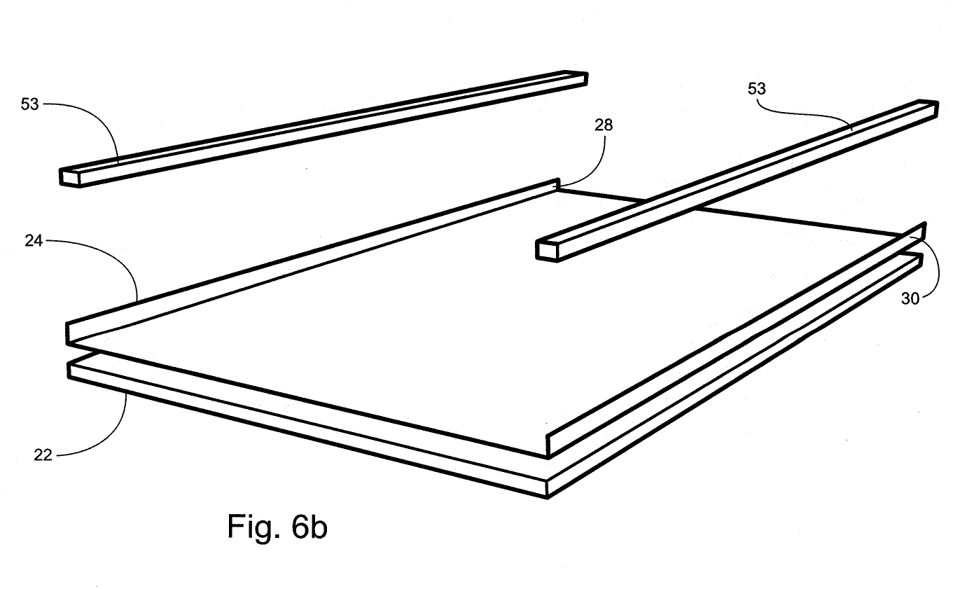

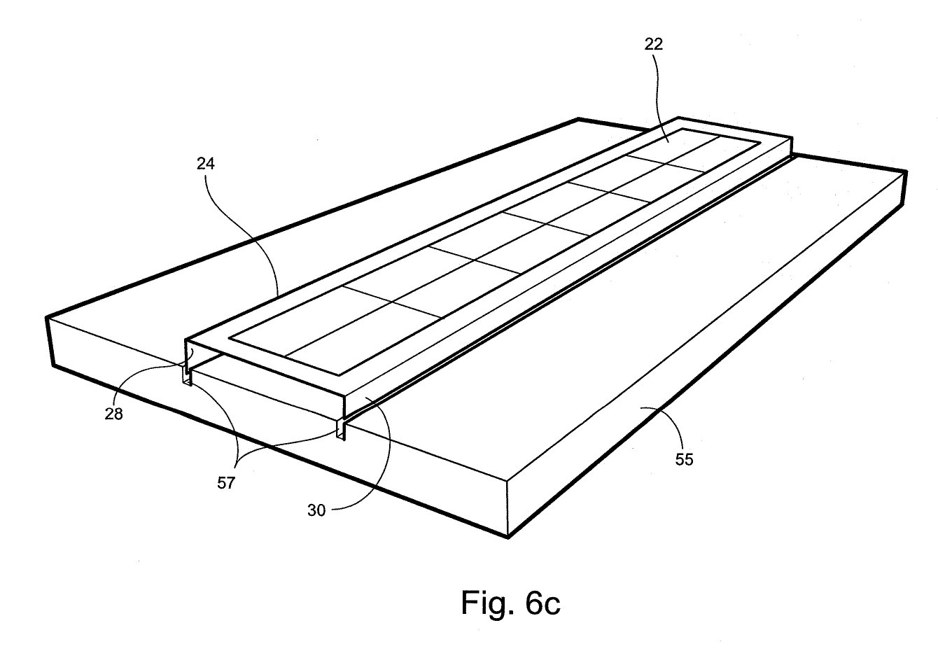

Referring to FIGS. 6a-c, illustrations of the construction of the lamination of the photovoltaic module 22 and the support panel 24 are shown. A metal block 52, or metal bars 53 (see FIG. 6b), having a predetermined thickness is applied to the top of the inverted support panel 24 to ensure flatness of the support panel during lamination. To construct the lamination, ETFE film of a predetermined dimension is laid out on a flat surface. A first layer of adhesive is applied on top of the ETFE film. Several string cells are then laid on top of the adhesive. A second layer of adhesive is applied on top of the solar strings followed by a back film/protection layer. A third layer of adhesive is applied on top of the back film, followed by the support panel 24. The metal block 52 or metal bars 53 is/are then added atop the underside of the support panel 24. Metal bars 53 are advantageous in that when placed adjacent the flanges and have a corresponding height, they protect the laminator from the sharp flanges by essentially increasing the surface area of the flange in contact with the laminator. Further, bars in contrast to metal block have a lesser volume and thus function as less of a heat sync, resulting in lesser heating times. The stacked layers of plastic, solar cells, support panel 24 and bars or block are placed into the laminator where they undergo a lamination process at a predetermined temperature, time period and pressure. The lamination is then allowed to cool before being removed. The lamination results in a cohesive photovoltaic module/support panel that can then be secured to a roof mount.

Referring to FIG. 6c, another lamination method is shown. To construct the lamination, support panel 24 is laid out on the heating plate 55 of the laminator with the flanges 28 and 30 positioned downward toward the heating plate. The heating plate 55 defines two elongate channels 57 for receiving the flanges 28 and 30 such that the underside of the support panel 24 is supported directly upon the heating plate to ensure flatness. In other words, the channels 57 provide clearance for the flanges during lamination, ensuring flatness of the support panel and obviating the need for adding/removing a metal block or metal bar that further absorbs heat, increasing lamination time. A first layer of adhesive is laid on top of the support panel 24. A back film/protection film of a predetermined dimension is laid out on the surface of 24. A second layer of adhesive is applied to the top of the back film. Several string cells are then laid on top of the adhesive. A third layer of adhesive is applied on top of the solar strings followed by an ETFE film.

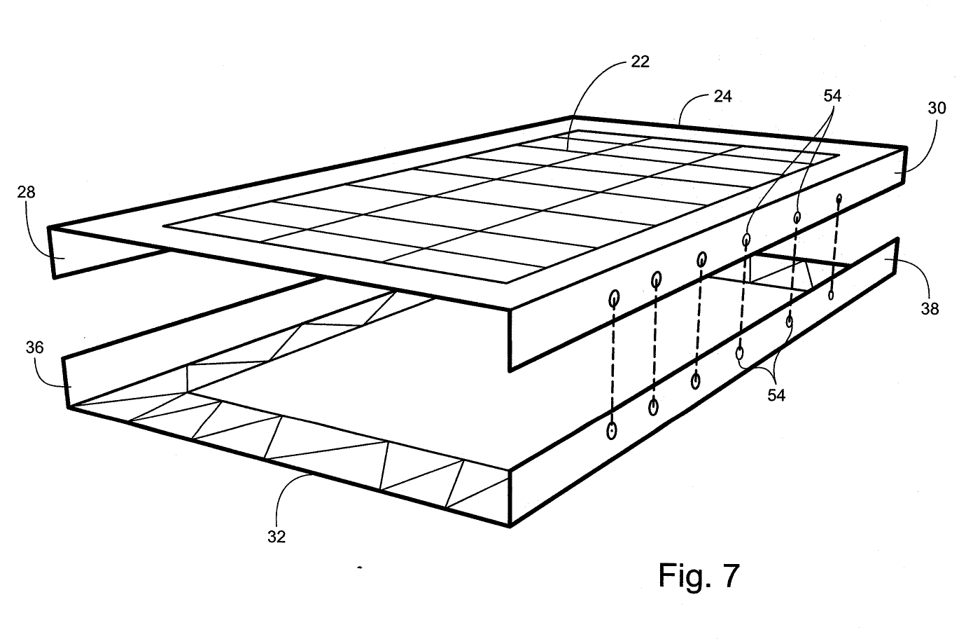

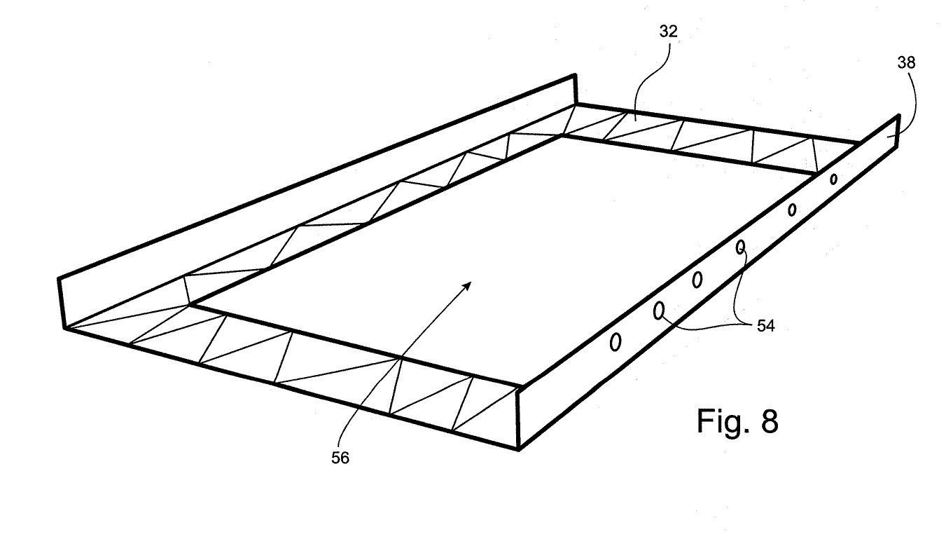

Referring to FIGS. 7 and 8, a plurality of openings 54 are defined through the flanges 28, 30, 36 and 38 of the corresponding support panel 24 and roof mount 32 for receiving conventional fasteners for securing the components together. The openings are aligned and the components secured together with the fasteners. The system installation method preferably includes first securing the roof mount 32 to the support panel 24, then securing the roof mount 32 to the roof. In an alternative installation method, the roof mount 32 may first be secured to the roof before attaching the support panel 24. Fastening may include using mechanical fasteners that may be removed to replace/uninstall a photovoltaic lamination, as well as permanent fastening methods such as welding. Securing the roof mount 32 to the roof may be accomplished using an adhesive, double-sided tape or one of the methods described in detail below. Referring specifically to FIG. 8, the center portion of the roof mount 32 indicated at reference number 56 may be open and devoid of material in order to save material, reduce costs and reduce weight. The open center may further be advantageous for installing the system over a protruding structure, further adding to the installation flexibility of the system. The systems of the present invention are advantageous in that installation at the construction site is simplified and the roof is not penetrated.

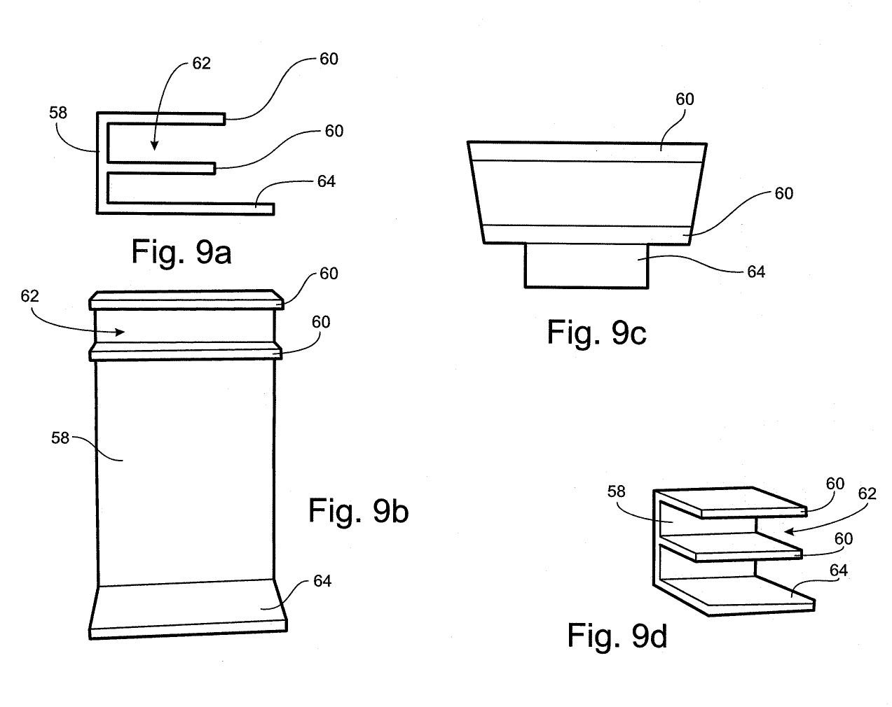

Referring to FIGS. 9a-d, various embodiments of alternative roof mounts are shown. Each of the illustrated mounts may be used to replace both the support panel 24 and roof mount 32 of the embodiment described above. Each roof mount is essentially a frame defining flanges forming a channel for retaining the photovoltaic module therein, and an additional flange spaced-apart from the channel forming flanges for being attached to the roof. Although the roof mounts are shown as having a relatively short length, it is intended that the roof mounts may have a length corresponding to the side to which they support, and may include corner supporting portions. To provide installation flexibility, the roof mounts may have a length shorter than the side that they support, allowing an installer to use multiple supports based on the panel size. Thus, a “universal” roof mount is provided.

Each roof mount includes a generally vertically extending member 58 having flanges 60, 64 extending laterally therefrom. Vertical member 58 may have any height dependent upon the desired distance of the photovoltaic module from the underlying roof. Flanges 60 together define a channel 62 therebetween for receiving and retaining the photovoltaic module. Flange 64 is secured to the roof, such as with double-sided tape or adhesive. In the embodiments shown, flange 64 defines a length longer than flanges 60 to support the photovoltaic module in the elevated position at the preferred slope for maximum sunlight absorption. The roof mounts are preferably constructed from rigid, corrosion-resistant materials.

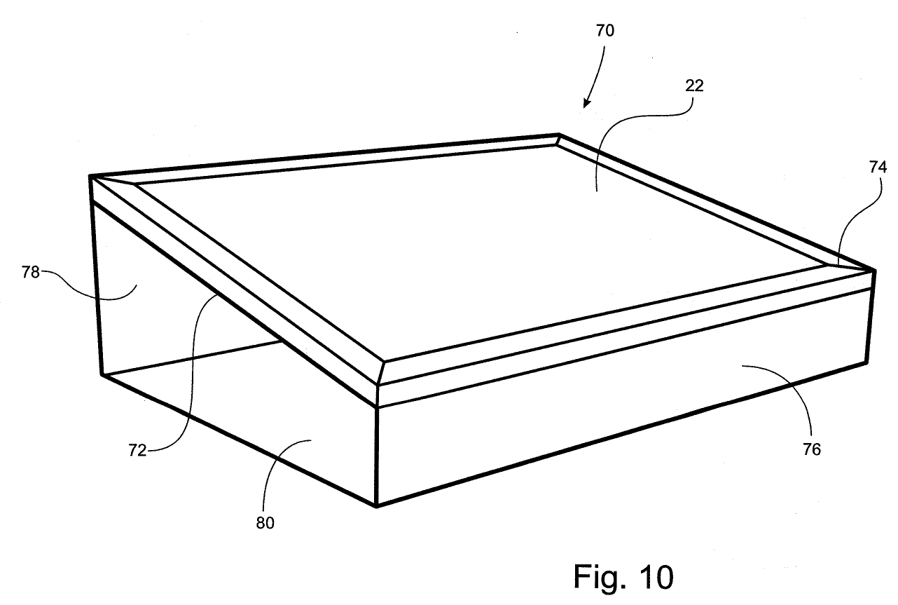

Referring to FIG. 10, an alternative embodiment of a photovoltaic lamination and roof mounting system is shown generally at reference number 70. The photovoltaic module 22 component of the system is essentially the same as described above in detail. The support panel 72 defines a frame 74 around the photovoltaic module 22 and maintains the photovoltaic module therein. Projecting vertically downward from the support panel 72 about one pair of opposing sides of the support panel are flanges 76, 78. One of the flanges 76, 78 has a length greater than the other to position the photovoltaic module 22 at a predetermined angle with respect to the generally horizontal underlying roof. In one example, the preferred angle of the photovoltaic module 22 with respect to the underlying roof and horizontal is about 15 degrees for optimal performance. The system 70 further includes horizontally extending base member 80 bridging the gap between and interconnecting the first and second flanges 76, 78. Again, the system is open on opposing ends to permit airflow therethrough for cooling. In embodiments in which the roof has a slope that does not correspond to the preferred slope of the photovoltaic module 22, the lengths of flanges 76, 78 may be customized to position the photovoltaic module 22 at the preferred slope.

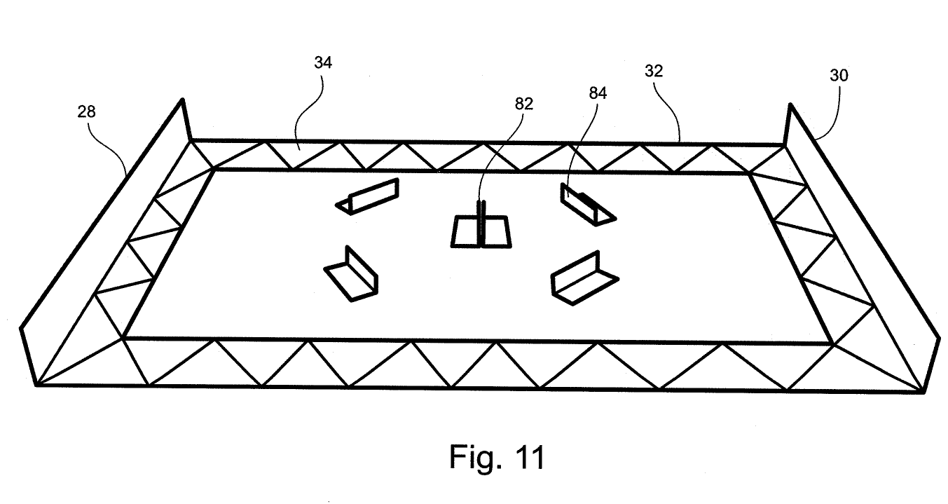

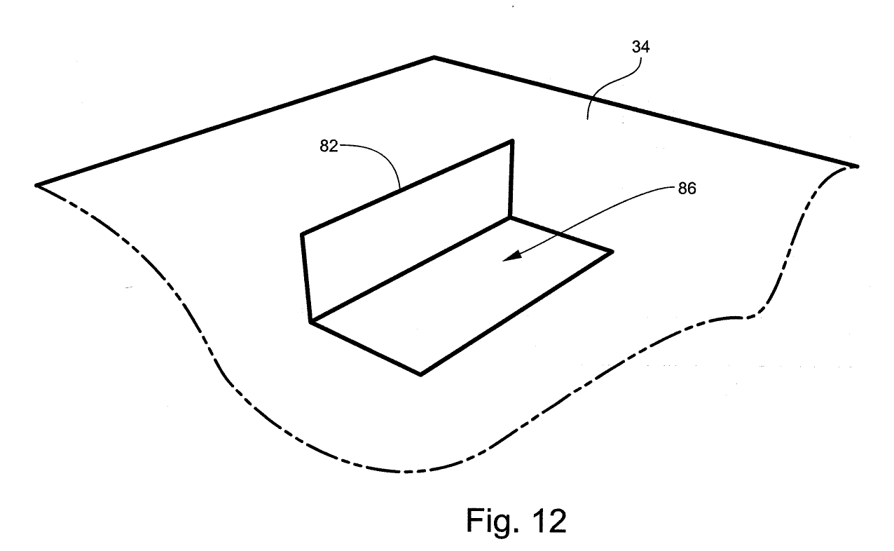

Referring to FIG. 11, a roof mount 32 configured for use with any of the embodiments described herein is shown removed from its overlying support panel and photovoltaic module. The roof mount 32 includes the base 34 which seats upon the roof and first and second flanges 28, 30 extending vertically upwardly from the base, such as about perpendicular to the base. Defined within about the center of the base 34 are internal flanges 82, 84 that are cut from the base and bent to about perpendicular thereto. The flanges 82, 84 function to aid in supporting the weight of the photovoltaic module, as well as reduce the airflow rate through the system to minimize the air lift effort. Thus, flanges 82, 84 may be strategically placed beneath the overlying support panel and may have a length corresponding to the length of flanges 28 and 30. As shown, flanges 82 are centrally positioned on the base 34 and flanges 84 are positioned radially around the center. It is envisioned that the flanges 82, 84 may have any length, and may be cut from and bent upwardly or a component added to the base and secured thereto. Referring to FIG. 12, a detailed view of a flange 82 is shown projecting from the base 34 illustrating the material void 86 left in the base 34 when the flange 82 is bent upwardly.

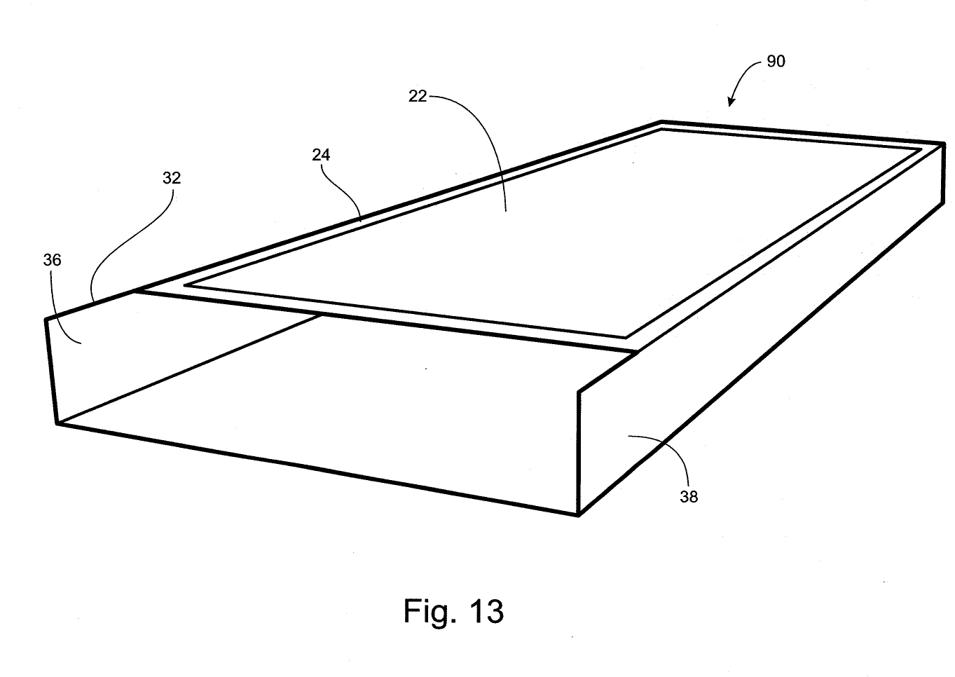

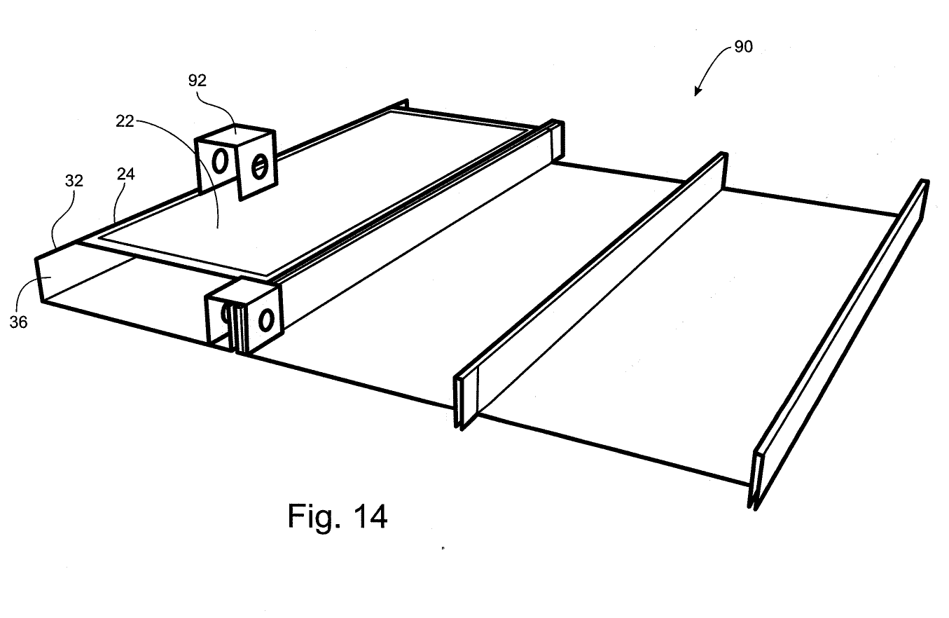

Referring to FIGS. 13-14, another embodiment of a photovoltaic lamination and roof mounting system is shown generally at reference number 90. The voltaic module 22 component of the system is essentially the same as described above in detail. The photovoltaic module 22 and support panel 24 lamination has a length less than the underlying roof mount 32 such that the ends of the flanges 36, 38 are exposed to receive mounting clamps 92 for securing the system to the underlying roof. As shown installed in FIG. 14, the underlying roof is of the type having roof panels intersecting at upwardly extending seams to reduce the potentially for leaks. The system 90 installs between adjacent seams with the flanges of the system 90 positioned adjacent the seams and clamped thereto with clamps 92. Clamp 92 defines a general C-shape having openings defined through opposing sides for receiving a conventional fastener. In one embodiment, the clamp is positioned over the seam and flange and a fastener is received therethrough. In an installation in which the fastener penetrates the roof, it is preferred that the penetration be through the upwardly extending seam in order to minimize the potential for leaking. Clamps 92 may be positioned at one or more of the corners to secure the system 90 to the roof. The support panel/photovoltaic module lamination may be produced with a width corresponding to the distance between seams.

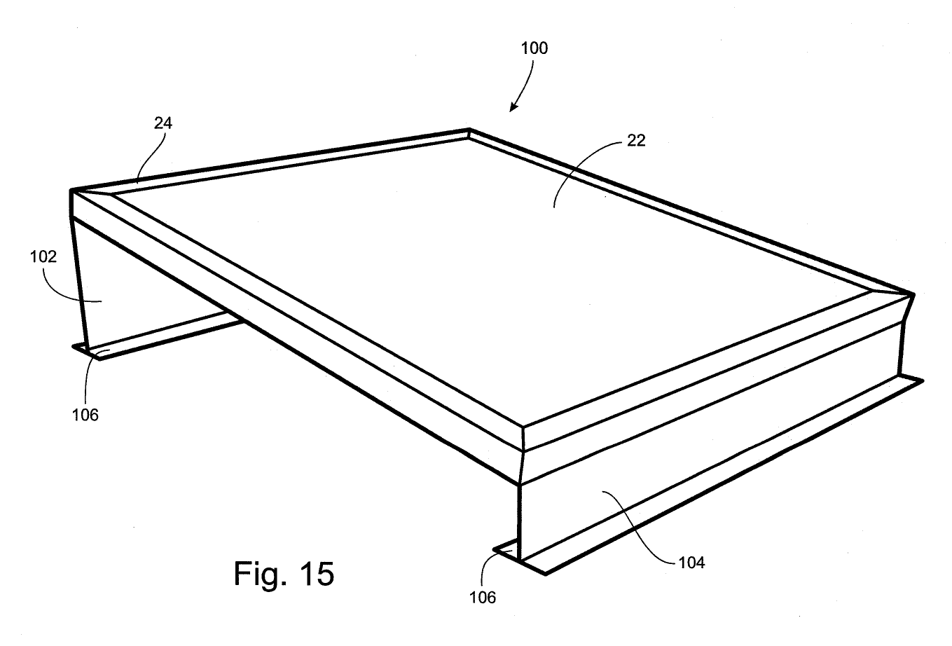

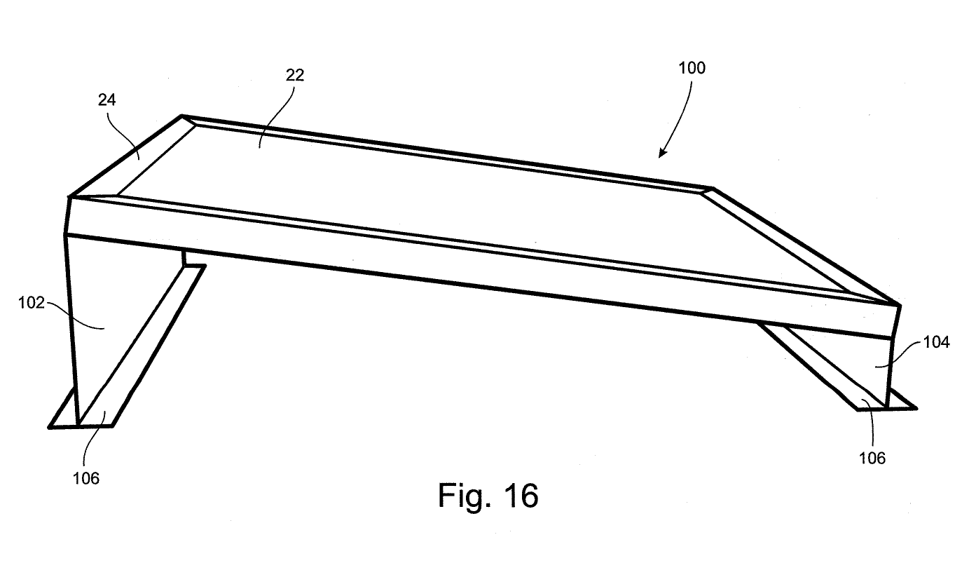

Referring to FIGS. 15-16, another embodiment of a photovoltaic lamination and roof mounting system is shown generally at reference number 100. The photovoltaic module 22 component of the system is essentially the same as described above in detail. The photovoltaic module 22 and support panel 24 are supported upon flanges 102, 104 that extend downward to be secured to the roof. At the base of each flange 102, 104, flanges 106 extend laterally therefrom to provide an adequate surface area for mounting to the roof and supporting the weight of the system 100. As in the previous embodiments, the flanges 102, 104 may have different lengths in order to provide a predetermined slope to the photovoltaic module 22 when mounted. This embodiment reduced the amount of material as compared to the embodiments shown in FIG. 10 in which the base covers the entire area underlying the support panel/photovoltaic module lamination. This embodiment may be further advantageously installed on rooftops or other structure that do not have a planar surface area large enough to accommodate the base 80 of FIG. 10.

While photovoltaic modules and associated roof mounting systems and methods have been described with reference to specific embodiments and examples, it is envisioned that various details of the invention may be changed without departing from the scope of the invention. Furthermore, the foregoing description of the preferred embodiments of the invention and best mode for practicing the invention are provided for the purpose of illustration only and not for the purpose of limitation.

### Experimental Results

Experiment #1. The lamination of a 140 W solar panel having a panel size of approximately 42″×39″ was performed. ETFE film (5 mil) was laid out on a flat surface. A first layer of XUS film (15 mil) was applied on top of the ETFE film. Several string cells were then laid on top of the XUS film. A second layer of XUS film was applied on top of the solar strings followed by an EPE (10 mil) layer, or a back protection sheet. The third layer of XUS film was applied on top of the back protection sheet. The support panel was added last. The metal block was added atop the underside of the support panel. The stacked layers of plastic, solar cells and substrate panel were placed into a laminator and underwent a lamination process at about 150 degrees C. for approximately 5 minutes an under 1 atmosphere of pressure (14.7 psi). The compressed solar panel was removed from the laminator after 5 minutes. The solar panel lamination was secured to the roof mount, which had been adhered to the roofing membrane at the installation site.

Experiment #2. The lamination of an 80 W solar panel having a panel size of approximately 70″×15″ was performed. First, the support panel was properly positioned on top of the heating plate of the laminator. A first layer of XUS film (15 mil) was laid on the surface of the support panel. An EPE (10 mil) layer, or a back protection sheet was laid out on a flat surface of the support panel. A second layer of XUS film (15 mil) was applied on top of the back protection sheet. Several string cells were then laid on top of the XUS film. A third layer of XUS film was applied on top of the solar strings followed by an ETFE film (5 mil) which was the last film added. The stacked layers of plastic, solar cells and substrate panel were placed into a laminator and underwent a lamination process at about 150 degrees C. for approximately 5 minutes an under 1 atmosphere of pressure (14.7 psi). The compressed solar panel was removed from the laminator after 5 minutes. The solar panel lamination was secured to the roof mount, which had been adhered to the roofing membrane at the installation site.

What is claimed is:

1. A photovoltaic system, comprising:
a lamination comprising a photovoltaic module arranged upon a support panel, the support panel defining a generally planar surface for supporting the photovoltaic module and first and second flanges positioned along opposing sides of the support panel and generally perpendicular to the generally planar surface, the first and second flanges extending in the direction away from the photovoltaic module;
a roof mount underlying the support panel and configured for attachment to an underlying roof, the roof mount comprising a generally planar base and first and second flanges positioned along opposing sides of the base and generally perpendicular to the base, the first and second flanges of the roof mount extending in the direction toward the support panel;
wherein the flanges of the support panel and the roof mount are substantially aligned and secured together to attach the support panel to the roof mount to position the photovoltaic module elevated from an underlying roof such that air is able to flow between an underside of the support panel and the base of the roof mount.

2. The photovoltaic system according to claim 1, wherein each of the first and second flanges of the support panel and roof mount define at least one opening therethrough for receiving a fastener to secure the support panel and the roof mount together.

3. The photovoltaic system according to claim 1, wherein the base of the roof mount includes an open center portion devoid of material.

4. The photovoltaic system according to claim 1, wherein the roof mount further comprises at least one internal flange extending upwardly toward the overlying support panel.

5. The photovoltaic system according to claim 4, further comprising a plurality of flanges positioned radially around the at least one internal flange.

6. The photovoltaic system according to claim 1, wherein the first flange of either the support panel or the roof mount has a length greater than its corresponding second flange in order to position the photovoltaic module at an angle with respect to the underlying roof mount.

7. The photovoltaic system according to claim 1, wherein opposing ends of the photovoltaic system between the first and second flanges are open to permit airflow therethrough.

8. The photovoltaic system according to claim 1, wherein ends of the first and second flanges of the roof mount extend beyond the length of the generally planar surface and are accessible for receiving at least one clamp for securing the first and second flanges to roof structure.

9. The photovoltaic system according to claim 1, wherein the photovoltaic module comprises a non-glass protective cover layer, a photovoltaic layer including one or more photovoltaic cells, and a back film layer, wherein the layers are bonded together with layers of adhesive material to form a lamination.

10. A photovoltaic system, comprising:
a support panel defining a generally planar support surface for supporting a photovoltaic module, and first and second flanges positioned along opposing sides of the support panel and generally perpendicular to the support surface;
a photovoltaic module secured to the support surface;
a roof mount underlying the support panel and configured for attachment to an underlying roof, the roof mount comprising a base and first and second flanges positioned along opposing sides of the base and generally perpendicular to the base;
wherein the first and second flanges of the support panel and the roof mount are aligned and secured together to attach the support panel to the roof mount to position the photovoltaic module elevated from an underlying roof such that air is able to flow between an underside of the support panel and the base of the roof mount.

11. The photovoltaic system according to claim 10, wherein each of the first and second flanges of the support panel and roof mount define at least one opening therethrough for receiving a fastener.

12. The photovoltaic system according to claim 10, wherein the base of the roof mount includes an open center portion devoid of material.

13. The photovoltaic system according to claim 10, wherein the roof mount further comprises at least one internal flange extending upwardly toward the overlying support panel.

14. The photovoltaic system according to claim 13, further comprising a plurality of flanges positioned radially around the at least one internal flange.

15. The photovoltaic system according to claim 10, wherein the first flange of either the support panel or the roof mount has a length greater than its corresponding second flange in order to position the photovoltaic module at an angle with respect to the underlying roof mount.

16. The photovoltaic system according to claim 10, wherein ends of the first and second flanges of the roof mount extend beyond the length of the generally planar surface and are accessible for receiving at least one clamp for securing the first and second flanges to roof structure.

17. A method for manufacturing a photovoltaic lamination, comprising:
creating a photovoltaic arrangement, comprising:
laying out a protective cover film on a flat surface;
applying a first layer of adhesive on top of the protective cover film;
applying at least one solar cell on top of the first layer of adhesive;
applying a second layer of adhesive on top of the at least one solar cell;
applying a back film on top of the second layer of adhesive;
applying a third layer of adhesive on top of the back film;
applying a support panel on top of the third layer of adhesive, the support panel having a generally planar support surface and first and second flanges positioned along opposing sides of the support panel and positioned generally perpendicular to the support surface and extending in the direction away from the at least one solar cell; and
laminating the photovoltaic arrangement at a predetermined temperature, time period and pressure to provide a photovoltaic lamination.

18. The method according to claim 17, further comprising securing the photovoltaic lamination to a roof mount having a base and first and second flanges positioned along opposing sides of the base and positioned generally perpendicular to the base, wherein the attached support panel and roof mount cooperatively position the photovoltaic lamination elevated from an underlying roof such that air is able to flow between an underside of the support panel and the base of the roof mount.

19. The method according to claim 17, further comprising applying a weighted member on top of the support panel to ensure flatness of the support panel during lamination.
